(19) United States
(12) Patent Application Publication
(10) Pub. No.: US 2026/0282228 A1
(43) Pub. Date: Sep. 17, 2026

(54) SUBSTRATE AND CABLE ASSEMBLY

(71) Applicant: Nissei Electric Co., Ltd., Hamamatsu-shi (JP)

(72) Inventors: Tien Duc HOANG TRONG, Hamamatsu-shi (JP); Yuya HASEGAWA, Hamamatsu-shi (JP)

(21) Appl. No.: 19/549,439

(22) Filed: Feb. 25, 2026

(30) Foreign Application Priority Data
Mar. 14, 2025 (JP) 2025-041328

(51) Int. Cl. H05K 1/11; H01R 12/59; H01R 12/63; H05K 1/02

(52) U.S. Cl. CPC H05K 1/117; H01R 12/592; H01R 12/63; H05K 1/028; H05K 1/118; H05K 2201/09418; H05K 2201/10356

(57) ABSTRACT

Provided is a cable assembly in which stress applied to a cable connection portion when a substrate is bent is suppressed and a stable connection state is maintained. A substrate is provided with: a plurality of first pads that is arranged in parallel along a first direction and extends along a second direction from a proximal end side to a distal end side; a plurality of second pads that is arranged in parallel along the first direction in a region apart from a distal end side of the first pads and that extends along the second direction; and a connection pad electrically connecting adjacent pads among the first pads. When a coaxial cable is connected to the substrate, an outer conductor is connected to a region not adjacent to the connection pad in the first pads.

### CROSS REFERENCE TO RELATED APPLICATIONS

This application claims priority to and the benefit of Japanese Application No. 2025-041328, filed Mar. 14, 2025; the content of which is hereby incorporated by reference in its entirety.

### BACKGROUND

### Technical Field

The present disclosure relates to a substrate to which a cable is connected to form a cable assembly, the substrate being used for wiring in an electronic device.

### Description of Related Art

A cable assembly in which a coaxial cable or the like is connected to a substrate is used for wiring in various electronic devices (for example, JP2011-076908A and JP2006-185741A).

A flexible substrate is used depending on the location where the cable assembly is used, and the substrate may be used in a bent state (for example, JP2006-167282A).

When a coaxial cable is connected to a substrate, it is common practice to solder an inner conductor and an outer conductor to a predetermined pad formed on the substrate, as illustrated in FIG. 7.

FIG. 8 is a cross-sectional view taken along line A-A of FIG. 7 when the substrate is bent in the width direction; however, in a case where the cable is connected to a flexible substrate by soldering, when the substrate is bent, a soldered portion is subjected to stress so as to follow curvature, and the soldered portion may crack.

Cracking of solder may cause poor electrical continuity between the cable and the pad, and may cause adverse effects such as signal loss and disturbance during transmission of a high-frequency signal even when electrical continuity is not completely lost.

In addition, solder is often more rigid than a flexible substrate, and there is also a problem in that it is difficult to bend the substrate to achieve a desired dimension.

### BRIEF SUMMARY

An object of an aspect of the present disclosure is to provide a cable assembly in which stress applied to a cable connection portion when a substrate is bent is suppressed and a stable connection state is maintained.

As a result of rigorous investigations by the present inventor(s) of the structure of a substrate used in a cable assembly, the present inventor(s) has found that the above problem can be solved by employing the following configurations.
(1) A substrate provided with:
   a plurality of first pads that is arranged in parallel along a first direction and extends along a second direction from a proximal end side to a distal end side;
   a plurality of second pads that is arranged in parallel along the first direction in a region apart from a distal end side of the first pads in the second direction and that extends along the second direction; and
   a connection pad electrically connecting adjacent pads among the first pads.
(2) The substrate described in (1) above, in which the connection pad is formed on a proximal end side of the first pads.
(3) The substrate described in (1) above, in which the connection pad is formed on the distal end side of the first pads.
(4) The substrate described in any of (1) to (3) above, in which a third pad that is electrically connected to the first pads and extends from the proximal end side of the first pads to a distal end side of the second pads in parallel to the first pads and the second pads is formed.
(5) The substrate described in any of (1) to (4) above, which has flexibility.
(6) A cable assembly in which a cable is connected to the substrate described in any of (1) to (5) above, in which
   the cable includes a first conductor and a second conductor,
   the first conductor is connected to the first pads,
   the second conductor is connected to the second pads, and
   the first conductor is connected to a region not adjacent to the connection pad in the first pads.
(7) The cable assembly described in (6) above, in which the cable is a coaxial cable having an inner conductor, an insulator that covers the inner conductor, and an outer conductor provided on an outer circumference of the insulator; the outer conductor is the first conductor; and the inner conductor is the second conductor.
(8) The cable assembly described in (6) above, in which the cable includes at least a drain wire and a transmission line; a conductor forming the drain wire is the first conductor; and a conductor forming the transmission line is the second conductor.
(9) The cable assembly described in any of (6) to (8) above, having the substrate described in (5) above, in which the substrate is bent along the first direction.

In addition, configurations obtained by appropriately selecting and combining the configurations described in (1) to (9) above also fall within the technical scope of the present disclosure.

According to an aspect of the present disclosure, a substrate and cable assembly in which cracking is unlikely to occur at a connection portion of a coaxial cable even when the substrate is bent are provided.

### BRIEF DESCRIPTION OF THE DRAWINGS

FIG. 1A to FIG. 1C each illustrate a structure of a substrate according to an aspect of the present disclosure;

FIG. 2 illustrates an example in which a coverlay is provided above the substrate according to an aspect of the present disclosure;

FIG. 3A and FIG. 3B each illustrate a modification of the substrate according to an aspect of the present disclosure;

FIG. 4 illustrates a cable assembly according to a first embodiment;

FIG. 5 is a schematic diagram illustrating the cable assembly according to the first embodiment in a bent state;

FIG. 6A and FIG. 6B illustrate a cable assembly according to a second embodiment;

FIG. 7 illustrates a conventional cable assembly; and

FIG. 8 is a schematic diagram illustrating stress generated when a substrate is bent.

### DETAILED DESCRIPTION OF VARIOUS EMBODIMENTS

A substrate 1 and a cable assembly 100 using the substrate 1 according to an aspect of the present disclosure are described below with reference to drawings. Note that the technical scope of the present disclosure is not limited to only the following descriptions or drawings.

### Structure of Substrate

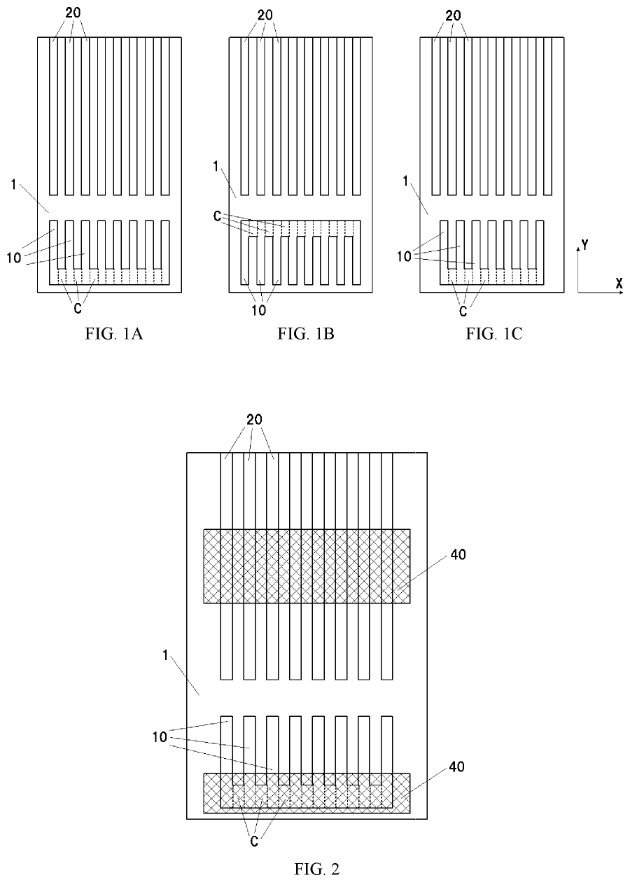

The substrate 1 of an aspect of the present disclosure is provided with a first pad 10, a second pad 20, and a connection pad C as illustrated in FIG. 1A.

While the substrate 1 illustrated in FIG. 1A has a rectangular shape, a specific shape of the substrate 1 is not particularly limited and is appropriately set according to an electronic device or the like in which the cable assembly 100 using the substrate 1 is used.

Dimensions of the substrate 1 are also appropriately set according to an electronic device or the like used; however, the width is typically set to about 2 mm to 10 mm, the length is typically set to about 5 mm to 15 mm, and the thickness is typically set to about 50 μm to 0.2 mm.

The width direction (the X direction in FIG. 1A) and the length direction (the Y direction in FIG. 1A) of the substrate 1 correspond to a first direction and a second direction, respectively, which will be described later.

A plurality of first pads 10 is formed on the substrate 1 so as to be adjacent to each other in parallel along the first direction, and each of the first pads 10 has a shape extending along the second direction from a proximal end side toward a distal end side of the substrate 1.

Dimensions of the first pads 10 are also appropriately set according to an electronic device used, a cable connected, or the like; however, the width is typically set to about 50 μm to 150 μm, the length is typically set to about 300 μm to 1000 μm, and the pitch is typically set to about 0.1 mm to 0.3 mm.

The width and pitch of the first pads 10 may be constant over the entire length or may be varied as desired.

In addition, a plurality of second pads 20 is formed on the substrate 1 so as to be adjacent to each other in parallel along the first direction, and the second pads 20 is formed in a region apart from a distal end side of the first pads 10 in the second direction.

Dimensions of the second pads 20 are also appropriately set according to an electronic device used, a cable connected, or the like; however, the width is typically set to about 50 μm to 150 μm, the length is typically set to about 300 μm to 1000 μm, and the pitch is typically set to about 0.1 mm to 0.3 mm.

The width and pitch of the second pads 20 may be constant over the entire length or may be varied as desired.

The connection pad C that electrically connects adjacent first pads 10 is further formed on the substrate 1.

The connection pad C may be formed at any location between the first pads 10, but is preferably formed on a proximal end side or distal end side of the first pads 10 unless there is a particular intention.

FIG. 1A illustrates a case in which the connection pad C is formed on the proximal end side of the first pads 10, and FIG. 1B illustrates a case in which the connection pad C is formed on the distal end side of the first pads 10

Although the number of the first pads 10 and the number of the second pads 20 are the same in the cases illustrated in FIG. 1A and FIG. 1B, an embodiment in which the number of the first pads 10 differs from the number of the second pads 20 as illustrated in FIG. 1C may also be adopted as desired.

The material of the substrate 1 used may be appropriately selected from resins commonly used as materials of substrates for electrical wiring, such as an epoxy-based resin, a polyimide-based resin, a polyethylene terephthalate-based resin, a phenolic resin, a silicone-based resin, a polyphenylene ether-based resin, a urethane-based resin, an acrylic resin, an olefin-based resin, an elastomer-based resin, a liquid crystal polymer-based resin, and a combination thereof.

When the substrate 1 is configured to be flexible, a polyimide-based resin, a polyethylene terephthalate-based resin, a silicone-based resin, a urethane-based resin, an acrylic resin, an olefin-based resin, and an elastomer-based resin may be preferably used.

Each pad formed on the substrate 1 is formed by using any of various metal materials used as an electrical conductor, such as copper, silver, gold, tin, aluminum, and an alloy thereof.

In order to protect the pads formed on the substrate 1, the surface of the substrate 1 may be partially covered with an insulating coverlay 40.

It is preferable that the coverlay 40 be provided so as to prevent solder from flowing to an undesired location during soldering of a cable 50 (for example, coaxial cable 510, multicore cable 520) described later.

In an arrangement example of the coverlay 40, the coverlay 40 is provided so as to cover a region in which the first pads 10 are connected by the connection pad C and cover an intermediate area between a proximal end side and distal end side of the second pads 20, as illustrated in FIG. 2.

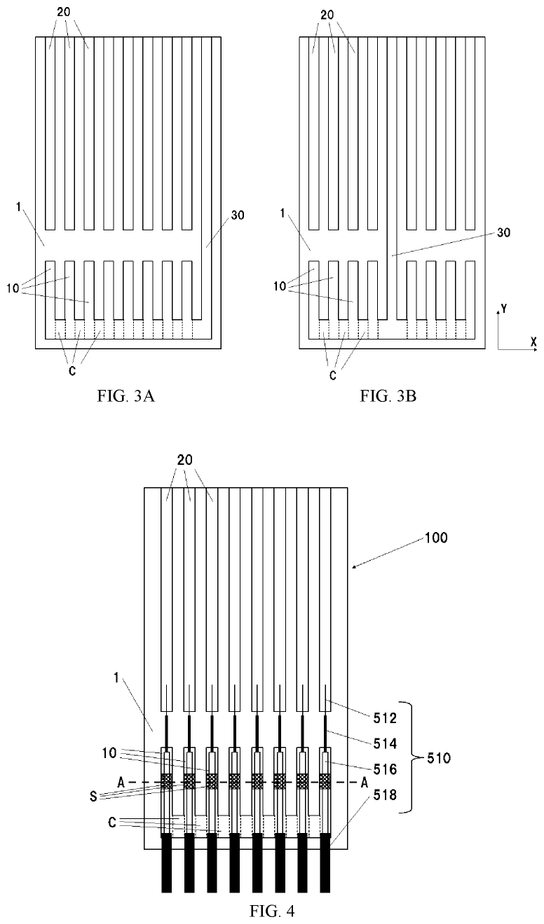

When it is preferred to extend the first pads 10 to the distal end side of the substrate 1 in relation to the configuration of a counterpart substrate or connector to which the substrate 1 is connected, as illustrated in FIG. 3A and FIG. 3B, a third pad 30 extending from the proximal end side of the first pads 10 to the distal end side of the second pads 20 may be formed in parallel with the first pads 10 and the second pads 20, and the third pad 30 may be electrically connected to the first pads 10.

In this configuration, the first pads 10 are substantially formed to reach the distal end side of the substrate 1.

The third pad 30 may be usually formed along a right periphery or a left periphery of the substrate 1; however, the third pad 30 may be formed in a region between the first pads 10 and the second pads 20, as desired. FIG. 3A illustrates a case in which the third pad 30 is formed along the right periphery of the substrate 1, and FIG. 3B illustrates a case in which the third pad 30 is formed in the vicinity of the center in the width direction of the substrate 1.

### Cable Assembly

The substrate 1 of an aspect of the present disclosure is used as the cable assembly 100 to which a cable 50 is connected.

The cable 50 connected to the substrate 1 of an aspect of the present disclosure includes a first conductor 51 and a second conductor 52, and the first conductor 51 is connected to the first pads 10 and the second conductor 52 is connected to the second pads 20, respectively.

At this time, the first conductor 51 is connected to a region not adjacent to the connection pad C in the first pads 10.

The first conductor 51 and the second conductor 52 are connected and fixed to the first pads 10 and the second pads 20 by soldering in general; however, by soldering the first conductor 51 to the region not adjacent to the connection pad C in the first pads 10, the solder remains within the first pads 10.

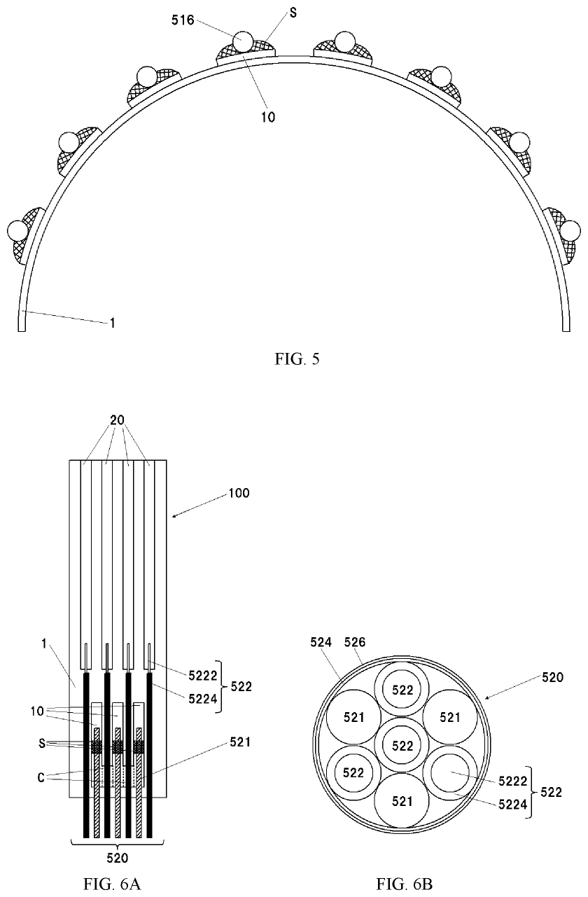

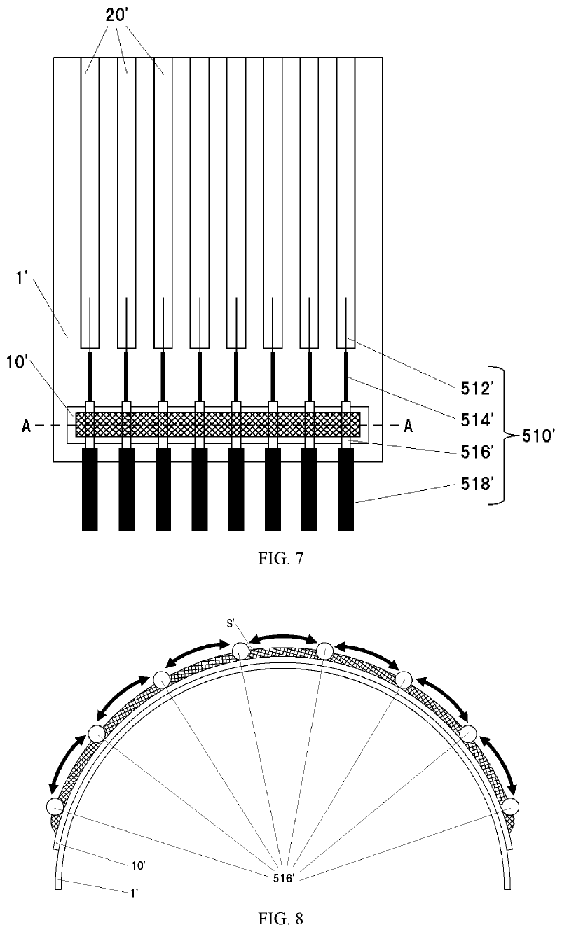

When the substrate 1 is flexible, the substrate 1 is sometimes bent along the first direction and used as illustrated in FIG. 5. Even in such a case, when the solder remains within the first pads 10, it is sufficient for the solder to follow the curvature within the width of the first pads 10 when the substrate 1 is bent, stress applied to the solder is thus reduced, and cracking of the solder is suppressed.

As a result, the connecting condition between the first conductor 51 and the first pads 10 is stabilized, and adverse effects such as poor electrical continuity, signal loss, and disturbance are suppressed.

In addition, the solder is less likely to hinder bending of the substrate 1, thereby facilitating bending of the substrate 1 to have a desired dimension.

In the case of the substrate 1 having a width of about 2 mm to 10 mm, a length of about 5 mm to 15 mm, and a thickness of about 50 μm to 0.2 mm as described above, the substrate 1 can be bent to have a minimum radius of 0.5 mm to 2 mm.

Since the solder remains within the second pads 20 also in the connection portion between the second conductor 52 and the second pads 20, the same effect as the connection portion between the first conductor 51 and the first pads 10 is obtained.

### First Embodiment

The cable assembly 100 according to a first embodiment is illustrated in FIG. 4.

The cable assembly 100 according to the first embodiment uses a coaxial cable 510 as the cable 50.

The coaxial cable 510 has an inner conductor 512, an insulator 514 covering the inner conductor 512, and an outer conductor 516 provided on an outer circumference of the insulator 514 in general. The outer conductor 516 is usually covered with an outer cover 518.

A specific configuration of the coaxial cable 510 is not particularly limited as long as the coaxial cable 510 has conductors respectively corresponding to the inner conductor 512 and the outer conductor 516, and a coaxial cable suitable for intended use or the like of the cable assembly 100 may be appropriately selected from heretofore proposed coaxial cables and used.

The cable assembly 100 according to the first embodiment is formed by connecting and fixing, to the substrate 1 of an aspect of the present disclosure, the coaxial cable 510 in which the inner conductor 512 and the outer conductor 516 are each exposed in a stepwise manner in a terminal portion, the outer conductor 516 is connected to the first pads 10, and the inner conductor 512 is connected to the second pads 20.

That is, the outer conductor 516 corresponds to the first conductor 51, and the inner conductor 512 corresponds to the second conductor 52.

Since the first pads 10 to which the outer conductor 516 is connected function as a grounding transmission path, it is preferable that each of the first pads 10 be set to a ground potential; however, when adjacent first pads 10 are connected by the connection pad C, the potentials of the respective first pads 10 are equalized.

FIG. 5 is a cross-sectional view taken along line A-A of FIG. 4 when the cable assembly 100 according to the first embodiment, which is formed using the substrate 1 having flexibility, is bent along the first direction. Even in such a case, when a soldered portion S remains within the first pads 10, it is sufficient for the solder to follow the curvature within the width of the first pads 10 when the substrate 1 is bent, stress applied to the solder is thus reduced, and cracking of the solder is suppressed.

In addition, the solder is less likely to hinder bending of the substrate 1, thereby facilitating bending of the substrate 1 to have a desired dimension.

### Second Embodiment

The cable assembly 100 according to a second embodiment is illustrated in FIG. 6A.

The cable assembly 100 according to the second embodiment uses, as the cable 50, a multicore cable 520 having a drain wire 521 and a transmission line 522.

In the multicore cable 520 used in the second embodiment, three drain wires 521 and four transmission lines 522 illustrated in FIG. 6B are twisted and covered with a shield layer 524 and a sheath 526.

The drain wires 521 illustrated in FIG. 6B are formed by twisting drain strands and are not covered with an insulation coating.

The drain wire 521 may be covered with an insulation coating as desired.

In each of the transmission lines 522 illustrated in FIG. 6B, a conductor 5222 obtained by twisting conductor strands is covered with an insulator 5224.

The transmission line 522 may be formed as a coaxial cable having an outer conductor as desired.

The transmission line 522 may transmit a signal or transmit electrical power.

The cable assembly 100 according to the second embodiment is formed by connecting the drain wires 521 to the first pads 10 and connecting the conductor 5222 forming the transmission lines 522 to the second pads 20.

That is, a conductor forming the drain wire 521 corresponds to the first conductor 51, and the conductor 5222 forming the transmission line 522 corresponds to the second conductor 52.

Since the first pads 10 to which the drain wires 521 are connected function as a grounding transmission path, it is preferable that each of the first pads 10 be set to a ground potential; however, when adjacent first pads 10 are connected by the connection pad C, the potentials of the respective first pads 10 are equalized.

Even in a case in which the substrate 1 having flexibility is used to form the cable assembly 100 according to the second embodiment, as the soldered portion S remains within the firsts pads 10, stress applied to the solder is reduced when the substrate 1 is bent.

In addition, the solder is less likely to hinder bending of the substrate 1, thereby facilitating bending of the substrate 1 to have a desired dimension.

While a configuration and embodiments of the substrate 1 and the cable assembly 100 of an aspect of the present disclosure are explained above, the specific form of the present disclosure is not limited thereto and the forms thereof can be modified as appropriate and put into practice within the scope of technical concepts of the present disclosure.

The substrate and the cable assembly of an aspect of the present disclosure can be preferably used for wiring and connection in various electronic devices when a coaxial cable and a substrate are used in combination.

What is claimed is:

1. A substrate, comprising:
a plurality of first pads arranged in parallel along a first direction and extending along a second direction from a proximal end to a distal end;
a plurality of second pads arranged in parallel along the first direction in a region apart from the distal end of the first pads in the second direction and that extends along the second direction; and
a connection pad electrically connecting adjacent pads among the first pads.

2. The substrate according to claim 1, wherein
the connection pad is formed on the proximal end of the first pads.

3. The substrate according to claim 1, wherein
the connection pad is formed on the distal end of the first pads.

4. The substrate according to claim 1, wherein
a third pad that is electrically connected to the first pads and extends from the proximal end of the first pads to a distal end of the second pads in parallel to the first pads and the second pads.

5. The substrate according to claim 1, which has flexibility.

6. A cable assembly comprising:
a cable connected to the substrate according to claim 1, wherein
the cable comprises a first conductor and a second conductor,
the first conductor is connected to the first pads,
the second conductor is connected to the second pads, and
the first conductor is connected to a region not adjacent to the connection pad in the first pads.

7. The cable assembly according to claim 6, wherein
the substrate has flexibility.

8. The cable assembly according to claim 7, wherein
the substrate is bent along the first direction.

9. The cable assembly according to claim 6, wherein
the cable is a coaxial cable having an inner conductor, an insulator that covers the inner conductor, and an outer conductor provided on an outer circumference of the insulator;
the outer conductor is the first conductor; and
the inner conductor is the second conductor.

10. The cable assembly according to claim 9, wherein
the substrate has flexibility.

11. The cable assembly according to claim 10, wherein
the substrate is bent along the first direction.

12. The cable assembly according to claim 6, wherein
the cable comprises at least a drain wire and a transmission line;
a conductor forming the drain wire is the first conductor; and
a conductor forming the transmission line is the second conductor.

13. The cable assembly described according to claim 12, wherein
the substrate has flexibility.

14. The cable assembly described according to claim 13, wherein
the substrate is bent along the first direction.
